(19) United States
(12) Patent Application Publication
(10) Pub. No.: US 2026/0240037 A1
(43) Pub. Date: Aug. 13, 2026

(54) SEMICONDUCTOR DEVICE

(71) Applicant: FUJI ELECTRIC CO., LTD., Kawasaki-shi (JP)

(72) Inventor: Ryoma KUDO, Matsumoto-city (JP)

(73) Assignee: FUJI ELECTRIC CO., LTD., Kawasaki-shi (JP)

(21) Appl. No.: 19/433,640

(22) Filed: Dec. 26, 2025

(30) Foreign Application Priority Data
Feb. 13, 2025 (JP) 2025-021241

(51) Int. Cl. H10W 76/157; H10W 90/00; H10W 90/10; H10W 40/47; H10W 72/00; H10W 74/10

(52) U.S. Cl. CPC H10W 76/157; H10W 90/10; H10W 90/755; H10W 90/764; H10W 40/47; H10W 72/871; H10W 74/114

(57) ABSTRACT

A semiconductor device, including: a semiconductor unit disposed on a heat dissipation base, and including a first semiconductor chip having a first control electrode; an outer peripheral wall in contact with the heat dissipation base, and surrounding the semiconductor unit to define a storage region with the heat dissipation base; a first connection terminal provided apart from the semiconductor unit in the storage region; a first bonding wire electrically connecting the first connection terminal and the first control electrode; a sealing member sealing the storage area; and a first partition member provided above the first semiconductor chip in the storage region, to divide the storage region into a first region and a second region. The first connection terminal and the first bonding wire are in the first region, and the first connection terminal is in the second region, in a plan view of the semiconductor device.

### CROSS-REFERENCE TO RELATED APPLICATIONS

This application is based upon and claims the benefit of priority of the prior Japanese Patent Application No. 2025-021241, filed on Feb. 13, 2025, the entire contents of which are incorporated herein by reference.

### BACKGROUND OF THE INVENTION

### Field of the Invention

The embodiments discussed herein relate to a semiconductor device.

### Background of the Related Art

In a semiconductor device, electrodes provided on semiconductor chips are electrically connected to connection terminals or wiring plates on an insulating substrate via bonding wires or lead frames.

As a related technique, a power semiconductor module including a case in which a partition plate is formed has been proposed (see, for example, Japanese Laid-open Patent Publication No. 2023-158794). In addition, a semiconductor device including a case including a beam portion has been proposed (see, for example, Japanese Laid-open Patent Publication No. 2022-077747). In addition, a semiconductor device in which a relaxation plate is provided on a side portion of a wire has been proposed (for example, see Japanese Laid-open Patent Publication No. 2020-107654). Further, a hybrid integrated circuit including a lid provided with a protrusion has been proposed (see, for example, Japanese Laid-open Patent Publication No. 2002-299521).

In addition, a semiconductor device including a resin cover provided with a rib wall has been proposed (see, for example, Japanese Laid-open Patent Publication No. 2002-246496). In addition, a semiconductor device including a plate-shaped member embedded in a sealing resin body has been proposed (for example, see International Publication Pamphlet No. WO 2002/059969). In addition, a semiconductor device including a heat dissipation plate in which a linear groove is formed has been proposed (for example, see Japanese Laid-open Patent Publication No. 2016-096188). Further, there has been proposed a semiconductor module including a partition portion that partitions the internal space of an outer frame (see, for example, Japanese Laid-open Patent Publication No. 2023-004394).

### SUMMARY OF THE INVENTION

According to an aspect of the present disclosure, there is provided a semiconductor device, including: a heat dissipation base having an upper surface; a semiconductor unit disposed on the upper surface of the heat dissipation base, the semiconductor unit including a first semiconductor chip that has a first control electrode on an upper surface of the first semiconductor chip; an outer peripheral wall having a lower end thereof in contact with the upper surface of the heat dissipation base, the outer peripheral wall surrounding the semiconductor unit to define a storage region with the upper surface of the heat dissipation base, the semiconductor unit being in the storage region; a first connection terminal provided apart from the semiconductor unit in the storage region; a first bonding wire electrically connecting the first connection terminal and the first control electrode of the first semiconductor chip; a sealing member sealing the storage area; and a first partition member provided above the first semiconductor chip in the storage region, to thereby divide the storage region into a first region and a second region, the first connection terminal and the first bonding wire being in the first region, and the first connection terminal being in the second region, in a plan view of the semiconductor device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view (part 1) of a semiconductor device according to a first embodiment;

FIG. 2 is a plan view (part 2) of the semiconductor device according to the first embodiment;

FIG. 3 is a side view of the semiconductor device according to the first embodiment;

FIG. 4 is a plan view of a semiconductor unit according to the first embodiment;

FIG. 5 is a cross-sectional view (part 1) of the semiconductor device according to the first embodiment;

FIG. 6 is a diagram illustrating connection between the semiconductor unit and various terminals;

FIG. 7 is a diagram illustrating an equivalent circuit of a function of a semiconductor module according to the first embodiment;

FIG. 8 is a cross-sectional view (part 2) of the semiconductor device according to the first embodiment;

FIG. 9 is a plan view of a semiconductor device according to a comparative example;

FIG. 10 is a cross-sectional view of the semiconductor device according to the comparative example;

FIG. 11 is an enlarged view of a main part of the cross-sectional view illustrated in FIG. 10;

FIG. 12 is a plan view of a semiconductor device according to a second embodiment;

FIG. 13 is a plan view of a semiconductor device according to a third embodiment; and

FIG. 14 is a cross-sectional view of the semiconductor device according to the third embodiment.

### DETAILED DESCRIPTION OF THE INVENTION

Hereinafter, embodiments will be described with reference to the drawings. In the following description, terms “front surface” and “upper surface” represent an X-Y plane facing upward (+Z direction) regarding the semiconductor devices illustrated in various drawings. Similarly, a term “up” represents an upward direction (+Z direction) regarding the semiconductor devices illustrated in various drawings. Terms “back surface” and “lower surface” represent an X-Y plane facing downward (−Z direction) regarding the semiconductor devices illustrated in various drawings. Similarly, a term “down” represents a downward direction (−Z direction) regarding the semiconductor devices illustrated in various drawings. The same directions are used in other drawings as needed. The terms “front surface”, “upper surface”, “up”, “back surface”, “lower surface”, “down”, and “side surface” are merely expressions for convenience of specifying a relative positional relationship, and do not limit the technical idea of any of the embodiments. For example, “up” and “down” may mean directions other than the vertical direction with respect to the ground. That is, the directions expressed by “up” and “down” are not limited to the gravity direction.

### First Embodiment

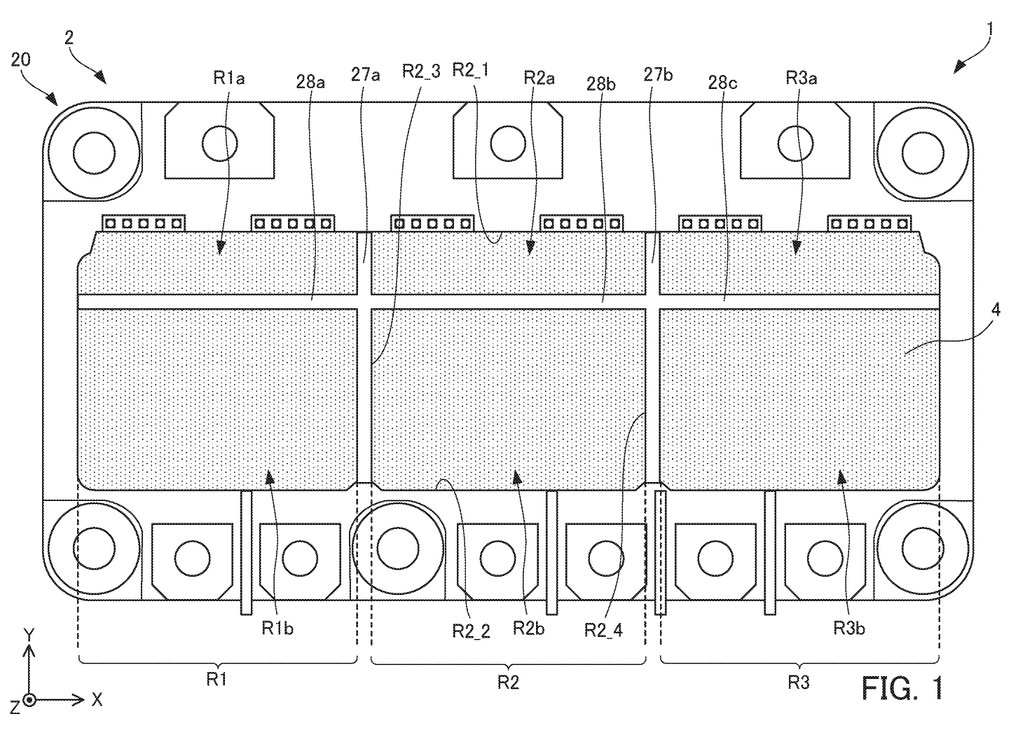

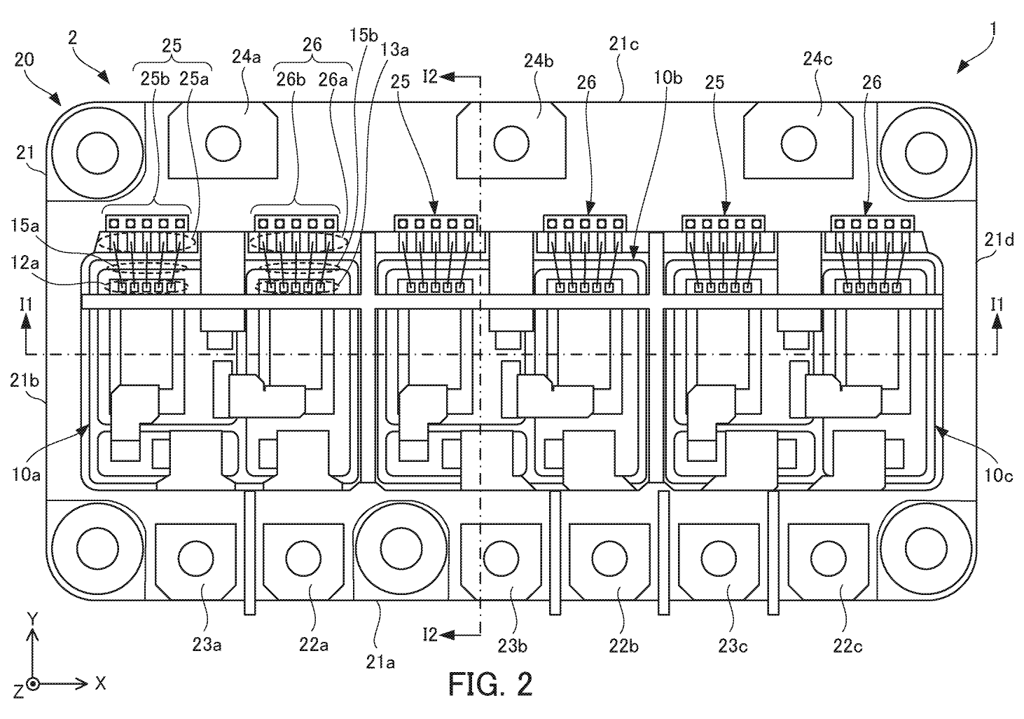

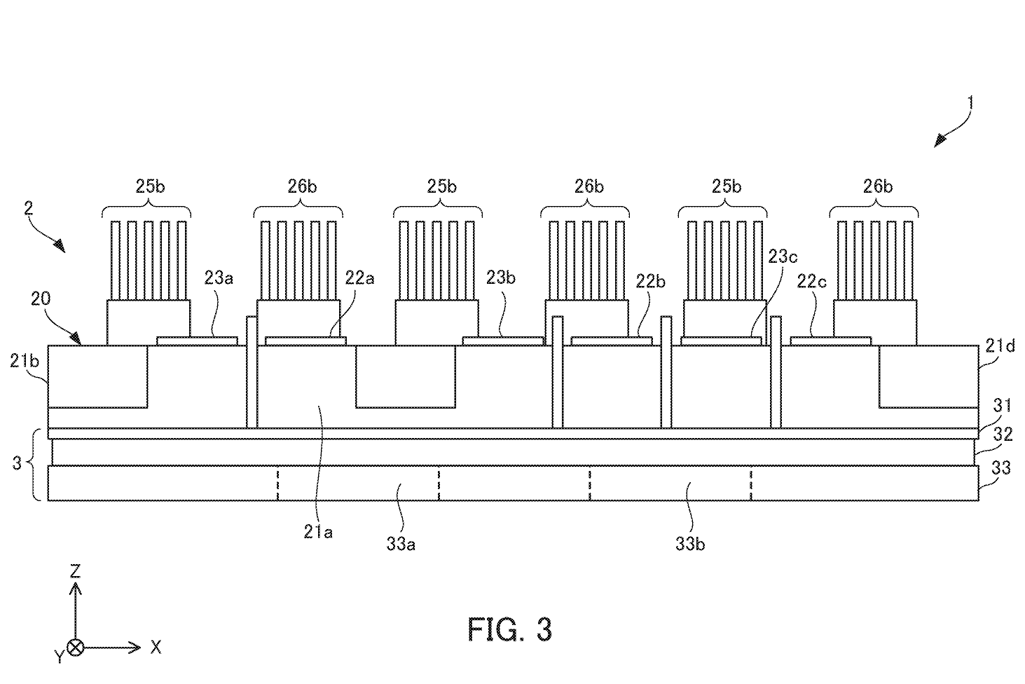

First, an overall configuration example of a semiconductor device according to a first embodiment will be described with reference to FIGS. 1 to 3. FIG. 1 is a plan view (part 1) of a semiconductor device according to a first embodiment. FIG. 2 is a plan view (part 2) of the semiconductor device according to the first embodiment. FIG. 3 is a side view of the semiconductor device according to the first embodiment. FIG. 2 is a plan view of the semiconductor device 1 in FIG. 1 without a sealing member 4. FIG. 3 is a side view of the semiconductor device 1 in FIG. 1 as viewed in the +Y direction.

The semiconductor device 1 includes a semiconductor module 2 and a cooling device 3. The semiconductor module 2 includes semiconductor units 10a, 10b, and 10c, and a case 20 that stores the semiconductor units 10a, 10b, and 10c. The case 20 is disposed on the cooling device 3, and the semiconductor units 10a, 10b, and 10c are arranged in a line in the +X direction inside the case 20. The semiconductor units 10a, 10b, and 10c stored in the case 20 are sealed by the sealing member 4.

The semiconductor units 10a, 10b, and 10c have the same configuration. Therefore, the semiconductor units 10a, 10b, and 10c will be described as “semiconductor units 10” when they are not distinguished from each other. Details of a semiconductor unit 10 will be described below.

The case 20 includes an outer frame 21, first connection terminals 22a, 22b, and 22c, second connection terminals 23a, 23b, and 23c, a U-phase output terminal 24a, a V-phase output terminal 24b, a W-phase output terminal 24c, and control terminal portions 25 and 26. The first connection terminals 22a, 22b, and 22c, the second connection terminals 23a, 23b, and 23c, the U-phase output terminal 24a, the V-phase output terminal 24b, the W-phase output terminal 24c, and the inner end portions (connection terminals 25a and 26a) of the control terminal portions 25 and 26 are each made of a solid plate-shaped metal material.

The outer frame 21 has a rectangular shape in plan view, and four sides thereof are sequentially surrounded by side walls 21a, 21b, 21c, and 21d. The side walls 21a and 21c are the long sides of the outer frame 21, and the side walls 21b and 21d are the short sides of the outer frame 21. In addition, in plan view, the corner portions, each of which is the connection portion of two of the side walls 21a, 21b, 21c, and 21d, may form an angle other than a right angle, and may be rounded as illustrated in FIG. 1, for example. The back surface of the outer frame 21 (the side walls 21a, 21b, 21c, and 21d) may form the same plane and be parallel to the X-Y plane.

The outer frame 21 includes storage regions R1, R2, and R3 along the side walls 21a and 21c (±X directions) in the ±Y direction center of the front surface. In each of the storage regions R1, R2, and R3, the corresponding front surface of the outer frame 21 is defined in a rectangular shape in plan view and is open. That is, the upper side (+Z direction side) of each of the storage regions R1, R2, and R3 forms an opening. However, as illustrated in FIG. 1, the openings of the storage regions R1, R2, and R3 are partitioned in the ±Y directions by partition members 28a, 28b, and 28c.

The semiconductor units 10a, 10b, and 10c are stored in the storage regions R1, R2, and R3, respectively. The storage regions R1, R2, and R3 may have any size, as long as the semiconductor units 10a, 10b, and 10c are stored therein. The bottom portions of the storage regions R1, R2, and R3 are covered by the upper surface of the cooling device 3 (the upper surface of a heat dissipation base 31 to be described below). A partition wall 27a is provided between the storage regions R1 and R2, and a partition wall 27b is provided between the storage regions R2 and R3. The entire lower ends of the partition walls 27a and 27b are in contact with the upper surface of the cooling device 3. That is, the storage region R1 is the space surrounded by the inner walls formed by the outer frame 21 of the case 20, the partition wall 27a, and the upper surface of the cooling device 3. The storage region R2 is the space surrounded by the inner walls formed by the outer frame 21 of the case 20, the partition walls 27a and 27b, and the upper surface of the cooling device 3. The storage region R3 is the space surrounded by the inner walls formed by the outer frame 21 of the case 20, the partition wall 27b, and the upper surface of the cooling device 3. For example, the storage region R2 is surrounded by inner walls R2_1 and R2_2 (first and second inner walls) formed by the outer frame 21, inner walls R2_3 and R2_4 (third and fourth inner walls) formed by the partition walls 27a and 27b, respectively, and the upper surface of the cooling device 3.

The storage regions R1, R2, and R3 are filled with the sealing member 4 up to the height of the upper ends of the partition walls 27a and 27b. The sealing member 4 is a thermosetting resin. As the thermosetting resin, for example, an epoxy resin or a silicone gel is used. In FIG. 1, the region filled with the sealing member 4 is hatched.

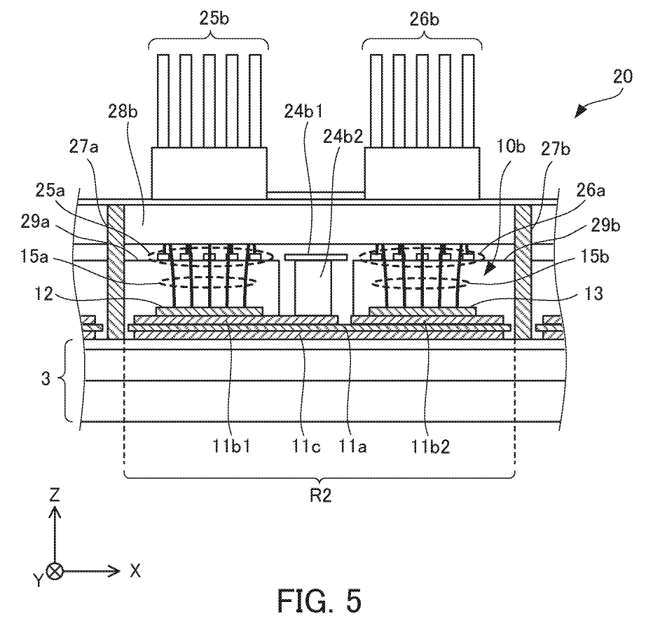

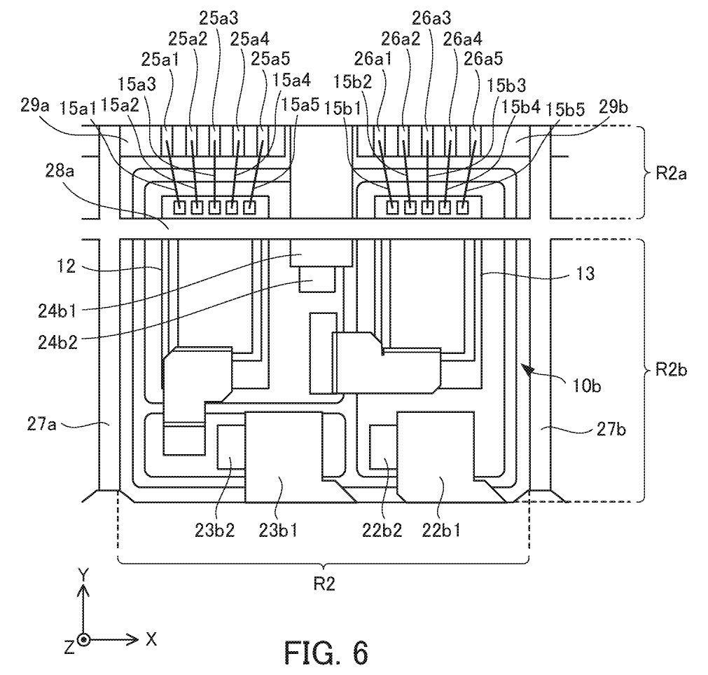

The semiconductor units 10a, 10b, and 10c are placed on the bottom surfaces of the storage regions R1, R2, and R3, that is, on the upper surface of the cooling device 3. Steps 29a and 29b (see FIGS. 5 and 6) protruding in the −Y direction are formed on the +Y direction inner walls of the storage regions R1, R2, and R3. The steps 29a and 29b have upper surfaces, and the height of the upper surfaces of the steps 29a and 29b is lower than the height of the partition walls 27a and 27b. The connection terminals 25a and 26a, which are the inner end portions of the control terminal portions 25 and 26, are provided on the upper surfaces of the steps 29a and 29b. Therefore, the semiconductor units 10a, 10b, and 10c and the connection terminals 25a and 26a are sealed by the sealing member 4 inside the storage regions R1, R2, and R3.

The first connection terminals 22a, 22b, and 22c and the second connection terminals 23a, 23b, and 23c are provided on the side wall 21a side of the front surface of the outer frame 21 along the side wall 21a (±X directions) in plan view. The first connection terminals 22a, 22b, and 22c are positive input terminals (P terminals), and the second connection terminals 23a, 23b, and 23c are negative input terminals (N terminals).

Further, the U-phase output terminal 24a, the V-phase output terminal 24b, and the W-phase output terminal 24c are provided on the side wall 21c side of the front surface of the outer frame 21 along the side wall 21c (±X directions). In this case, the first connection terminal 22a and the second connection terminal 23a are provided on one side of the storage region R1, and the U-phase output terminal 24a is provided on the other side of the storage region R1. The first connection terminal 22b and the second connection terminal 23b are provided on one side of the storage region R2, and the V-phase output terminal 24b is provided on the other side of the storage region R2. The first connection terminal 22c and the second connection terminal 23c are provided on one side of the storage region R3, and the W-phase output terminal 24c is provided on the other side of the storage region R3.

The control terminal portions 25 and 26 are provided between the storage regions R1, R2, and R3 and the U-phase output terminal 24a, the V-phase output terminal 24b, and the W-phase output terminal 24c in plan view. The control terminal portions 25 and 26 are provided for each of the storage regions R1, R2, and R3. Intermediate portions of the control terminal portions 25 and 26 are embedded in the outer frame 21. The inner end portions of the control terminal portions 25 and 26 are exposed to the inside of the storage regions R1, R2, and R3 from the +Y direction inner wall of the storage regions R1, R2, and R3 (for example, the inner wall R2_1). The inner end portions of the control terminal portions 25 and 26 form the flat plate-shaped connection terminals 25a and 26a parallel to the X-Y plane and are located on the upper surfaces of the steps 29a and 29b. On the other hand, the outer end portions of the control terminal portions 25 and 26 are exposed upward (+Z direction) from the upper surface of the outer frame 21, to form columnar external connection terminals 25b and 26b.

The outer frame 21 includes the first connection terminals 22a, 22b, and 22c, the second connection terminals 23a, 23b, and 23c, the U-phase output terminal 24a, the V-phase output terminal 24b, the W-phase output terminal 24c, and the control terminal portions 25 and 26, and is integrally molded by injection molding using a thermoplastic resin. In this way, the case 20 is formed. The thermoplastic resin is, for example, a polyphenylene sulfide resin, a polybutylene terephthalate resin, a polybutylene succinate resin, a polyamide resin, or an acrylonitrile butadiene styrene resin.

The first connection terminals 22a, 22b, and 22c, the second connection terminals 23a, 23b, and 23c, the U-phase output terminal 24a, the V-phase output terminal 24b, the W-phase output terminal 24c, and the control terminal portions 25 and 26 are made of a metal having excellent electrical conductivity. The metal is, for example, copper, aluminum, or an alloy containing at least one of them as a main component. The surfaces of the first connection terminals 22a, 22b, and 22c, the second connection terminals 23a, 23b, and 23c, the U-phase output terminal 24a, the V-phase output terminal 24b, the W-phase output terminal 24c, and the control terminal portions 25 and 26 may be plated. In this case, the plating material used is, for example, nickel, a nickel-phosphorus alloy, or a nickel-boron alloy. The plated first connection terminals 22a, 22b, and 22c, second connection terminals 23a, 23b, and 23c, U-phase output terminal 24a, V-phase output terminal 24b, W-phase output terminal 24c, and control terminal portions 25 and 26 have improved corrosion resistance.

In the following description, when the first connection terminals 22a, 22b, and 22c are not particularly distinguished from each other, they will be referred to as “first connection terminals 22”. Similarly, the second connection terminals 23a, 23b, and 23c will be referred to as “second connection terminals 23”, and the U-phase output terminal 24a, the V-phase output terminal 24b, and the W-phase output terminal 24c will be referred to as “output terminals 24”.

The cooling device 3 includes the heat dissipation base 31, a side wall 32 and a cooling bottom plate 33. The heat dissipation base 31 is a flat plate-shaped metal member having a rectangular shape in plan view. Corner portions of the heat dissipation base 31 in plan view may be rounded. The semiconductor units 10a, 10b, and 10c are bonded to the front surface of the heat dissipation base 31 along the X direction. A plurality of heat dissipation fins (not illustrated) are formed on the back surface of the heat dissipation base 31. The heat dissipation fins have, for example, a flat plate shape parallel to the X-Z plane and are arranged in line in the Y direction. The side wall 32 is continuously formed in an annular shape on the back surface of the heat dissipation base 31. The cooling bottom plate 33 has a flat plate shape and has the same shape as the heat dissipation base 31 in plan view. Corner portions of the cooling bottom plate 33 may also be rounded. The cooling bottom plate 33 has an inflow port 33a through which refrigerant flows into the cooling device 3, and has an outflow port 33b through which the refrigerant flowing through the cooling device 3 flows out to the outside.

The cooling device 3 cools the semiconductor units 10 by discharging the heat from the semiconductor units 10 via the refrigerant. The refrigerant used here is, for example, water, antifreeze (ethylene glycol aqueous solution), or long-life coolant. The cooling device 3 may include a pump and a heat dissipation device (radiator). The pump circulates the refrigerant by causing the refrigerant to flow into the inflow port 33a and by causing the refrigerant that has flowed out of the outflow port 33b to flow into the inflow port 33a again. The heat dissipation device receives the refrigerant that has flowed out of the cooling device 3 and dissipates the heat of the refrigerant, to which the heat of the semiconductor unit 10 has been conducted, to the outside. A water distribution head is attached to the inflow port 33a and the outflow port 33b via an annular rubber seal attached to a sealing region that surrounds the periphery of the inflow port 33a and the outflow port 33b. A water distribution pipe connected to the pump is attached to the water distribution head.

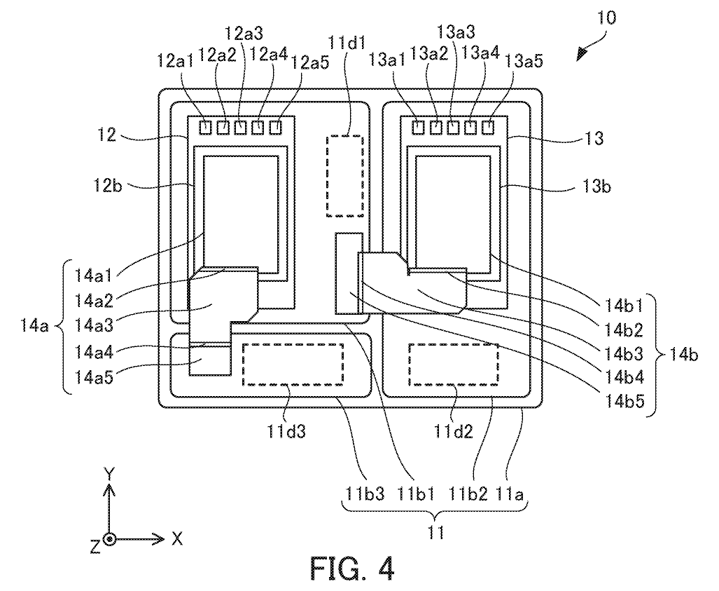

Next, the semiconductor units 10 will be described with reference to FIGS. 4 to 6. FIG. 4 is a plan view of a semiconductor unit according to the first embodiment. FIG. 5 is a cross-sectional view (part 1) of the semiconductor device according to the first embodiment. FIG. 6 is a diagram illustrating connection between the semiconductor unit and various terminals. FIG. 5 is an enlarged cross-sectional view of the semiconductor unit 10b of the semiconductor device 1, taken along line I1-I1 in FIG. 2. FIG. 6 illustrates the semiconductor unit 10b stored in the storage region R2. In FIGS. 5 and 6, illustration of the sealing member 4 is omitted.

The semiconductor unit 10 includes an insulating substrate 11, semiconductor chips 12 and 13, and wiring members 14a and 14b. The semiconductor chips 12 and 13 are bonded to the insulating substrate 11 via a bonding material. The wiring members 14a and 14b are bonded to the semiconductor chips 12 and 13, respectively, via a bonding material. Solder or a sintered material may be used as the bonding material. Each of the wiring members 14a and 14b is a solid plate-shaped metal material.

The insulating substrate 11 includes an insulating plate 11a, wiring plates 11b1, 11b2, and 11b3, and a metal plate 11c. The insulating plate 11a and the metal plate 11c are rectangular in plan view. Corner portions of the insulating plate 11a and the metal plate 11c may be rounded or chamfered. The size of the metal plate 11c is smaller than the size of the insulating plate 11a in plan view, and the metal plate 11c is formed inside the insulating plate 11a.

The insulating plate 11a is made of a material having an insulating property and excellent thermal conductivity. The insulating plate 11a may be made of ceramics or insulating resin. Examples of the ceramics include aluminum oxide, aluminum nitride, and silicon nitride. The insulating resin is, for example, a paper phenol substrate, a paper epoxy substrate, a glass composite substrate, or a glass epoxy substrate.

The wiring plates 11b1, 11b2, and 11b3 are formed on the front surface of the insulating plate 11a. The wiring plates 11b1, 11b2, and 11b3 are made of a metal containing copper and having excellent electrical conductivity. The metal may be, for example, an alloy containing aluminum in addition to copper.

The wiring plate 11b2 occupies approximately half of the +X direction side of the front surface of the insulating plate 11a, and ranges from the −Y direction side to the +Y direction side. The wiring plate 11b1 (a first wiring pattern) occupies approximately half of the −X direction side of the front surface of the insulating plate 11a. The wiring plate 11b3 (a second wiring pattern) occupies a region surrounded by the wiring plates 11b1 and 11b2 on the front surface of the insulating plate 11a.

The wiring plates 11b1, 11b2, and 11b3 are formed on the front surface of the insulating plate 11a as follows. A metal plate is formed on the front surface of the insulating plate 11a, and processing such as etching is performed on the metal plate, so as to obtain the wiring plates 11b1, 11b2, and 11b3 having a predetermined shape. Alternatively, the wiring plates 11b1, 11b2, and 11b3 cut out from a metal plate in advance may be pressure-bonded to the front surface of insulating plate 11a. These wiring plates 11b1, 11b2, and 11b3 are examples. The number, shape, size, and position of the wiring plates may be appropriately selected as needed.

The metal plate 11c is formed on the back surface of the insulating plate 11a. The metal plate 11c has a rectangular shape. The area of the metal plate 11c in plan view is smaller than the area of the insulating plate 11a and larger than the area of the region where the wiring plates 11b1, 11b2, and 11b3 are formed. Corner portions of the metal plate 11c may be rounded or chamfered. For example, the metal plate 11c is formed on the entire surface of the insulating plate 11a, except for the edges of the insulating plate 11a. The metal plate 11c is mainly made of a metal having excellent thermal conductivity. The metal is, for example, copper, aluminum, or an alloy containing at least one of these metals.

When the insulating plate 11a is made of ceramics, for example, a direct copper bonding (DCB) substrate or an active metal brazed (AMB) substrate may be used as the insulating substrate 11 having the above-described configuration. When the insulating plate 11a is made of an insulating resin, a resin insulating substrate may be used. The insulating substrate 11 may be attached to the front surface of the heat dissipation base 31 of the cooling device 3 via a bonding member. The heat generated by the semiconductor chips 12 and 13 is conducted to the cooling device 3 via the wiring plates 11b1 and 11b2, the insulating plate 11a, and the metal plate 11c, and is dissipated.

The semiconductor chips 12 and 13 include a power device element made of silicon. The power device element is a reverse-conducting insulated gate bipolar transistor (RC-IGBT). The RC-IGBT has both functions of an IGBT as a switching element and a freewheeling diode (FWD) as a diode element.

The front surface of the semiconductor chip 12 has a rectangular shape in plan view, and control electrodes 12a and an emitter electrode 12b (output electrode) as a main electrode are formed on the front surface of the semiconductor chip 12. In the present embodiment, the control electrodes 12a are provided on one short side of the front surface of the semiconductor chip 12. The control electrodes 12a are connected to the connection terminals 25a via bonding wires 15a.

More specifically, on the front surface of the semiconductor chip 12, five control electrodes 12a1, 12a2, 12a3, 12a4, and 12a5 are arranged in line in the +X direction as the control electrodes 12a. Further, five connection terminals 25a1, 25a2, 25a3, 25a4, and 25a5 as the connection terminals 25a are arranged in line in the +X direction on the upper surface of the step 29a formed on the inner wall of the storage region R2. Five connection terminals are also arranged in line in the same way on the inner wall of each of the storage regions R1 and R3. The control electrodes 12a1, 12a2, 12a3, 12a4, and 12a5 are connected to the connection terminals 25a1, 25a2, 25a3, 25a4, and 25a5 via bonding wires 15a1, 15a2, 15a3, 15a4, and 15a5, respectively. As described below, among the control electrodes 12a1, 12a2, 12a3, 12a4, and 12a5, the control electrode 12a3 serves as the gate electrode of the semiconductor chip 12.

The emitter electrode 12b is provided on the −Y direction short side of the front surface of the semiconductor chip 12. A collector electrode (an input electrode, not illustrated) as a main electrode is formed on the back surface of the semiconductor chip 12. The collector electrode is bonded to the wiring plate 11b1 via a bonding material.

The semiconductor chip 13 has a configuration similar to that of the semiconductor chip 12. Control electrodes 13a and an emitter electrode 13b (an output electrode) are formed on the front surface of the semiconductor chip 13, and a collector electrode (an input electrode, not illustrated) is formed on the back surface of the semiconductor chip 13. The collector electrode is bonded to the wiring plate 11b2 via a bonding material. The control electrodes 13a are connected to the connection terminals 26a via bonding wires 15b.

More specifically, on the front surface of the semiconductor chip 13, five control electrodes 13a1, 13a2, 13a3, 13a4, and 13a5 are arranged in line in the +X direction as the control electrodes 13a. Further, five connection terminals 26a1, 26a2, 26a3, 26a4, and 26a5 as the connection terminals 26a are arranged in line in the +X direction on the upper surface of the step 29b formed on the inner wall of the storage region R2. Five connection terminals are also arranged in the same way on the inner wall of each of the storage regions R1 and R3. The control electrodes 13a1, 13a2, 13a3, 13a4, and 13a5 are connected to the connection terminals 26a1, 26a2, 26a3, 26a4, and 26a5 via bonding wires 15b1, 15b2, 15b3, 15b4, and 15b5, respectively. As will be described below, among the control electrodes 13a1, 13a2, 13a3, 13a4, and 13a5, the control electrode 13a3 serves as the gate electrode of the semiconductor chip 13.

The bonding wires 15a and 15b are made mainly of a material having excellent electrical conductivity. The material includes, for example, gold, copper, aluminum, or an alloy containing at least one of these metals. Preferably, the bonding wires 15a and 15b may be made of an aluminum alloy containing a small amount of silicon. The diameter of the bonding wires 15a and 15b may be, for example, 20 μm or more and 500 μm or less.

Each of the semiconductor chips 12 and 13 may include a set of a switching element and a diode element, instead of the RC-IGBT. The switching element is, for example, an IGBT or a power metal-oxide-semiconductor field-effect transistor (MOSFET). Each of the semiconductor chips 12 and 13 includes, for example, an input electrode (a drain electrode or a collector electrode) as a main electrode on its back surface, and a control electrode (a gate electrode) and an output electrode (a source electrode or an emitter electrode) as a main electrode on its front surface. The diode element is, for example, a Schottky barrier diode (SBD) or a P-intrinsic-N (PiN) diode, and these are used as an FWD. Each of the semiconductor chips 12 and 13 includes an output electrode (a cathode electrode) as a main electrode on its back surface and an input electrode (an anode electrode) as a main electrode on its front surface.

Each of the semiconductor chips 12 and 13 may include a switching element formed of a power MOSFET made mainly of silicon carbide. In this case, the semiconductor chips 12 and 13 include an FWD together with a power MOSFET. Each of the semiconductor chips 12 and 13 includes a control electrode (a gate electrode) and an output electrode (a source electrode) as a main electrode on its front surface. Each of the semiconductor chips 12 and 13 has an input electrode (a drain electrode), which is a main electrode, on its back surface.

The wiring member 14a connects the emitter electrode 12b on the front surface of the semiconductor chip 12 and the wiring plate 11b3. The front surface of the wiring plate 11b3 includes a bonding region 11d3 to which a connection member for electrically connecting to a corresponding second connection terminal 23 is bonded. The inner end portion of the second connection terminal 23 is exposed to the inside from the −Y direction inner wall of the storage region R2. The inner end portion of each of the other second connection terminals 23 is exposed to the inside from the −Y direction inner wall of a corresponding one of the storage regions R1 and R3. The inner end portion has a flat plate shape, and a copper block is bonded to the lower surface of the inner end portion as the connection member. The lower surface of the copper block is bonded to the bonding region 11d3 of the wiring plate 11b3 via a bonding material. For example, an inner end portion 23b1 of the second connection terminal 23b is exposed to the inside from the inner wall R2_2 of the storage region R2, and a copper block 23b2 is bonded to the lower surface of the inner end portion 23b1 via a bonding material or by laser welding. The lower surface of the copper block 23b2 is bonded to the bonding region 11d3 of the wiring plate 11b3 via a bonding material. With this configuration, the wiring plate 11b3 and the second connection terminal 23b are electrically connected to each other.

The wiring member 14b connects the emitter electrode 13b on the front surface of the semiconductor chip 13 and the wiring plate 11b1. The front surface of the wiring plate 11b1 includes a bonding region 11d1 to which a connection member for electrically connecting to a corresponding output terminal 24 is bonded. The inner end portion of the output terminal 24 is exposed to the inside from the +Y direction inner wall of the storage region R2. The inner end portion of each of the other output terminals 24 is exposed to the inside from the +Y direction inner wall of a corresponding one of the storage regions R1 and R3. The inner end portion has a flat plate shape, and a copper block is bonded to the lower surface of the inner end portion as the connection member. The lower surface of the copper block is bonded to the bonding region 11d1 of the wiring plate 11b1 via a bonding material. For example, an inner end portion 24b1 of the V-phase output terminal 24b is exposed to the inside from the inner wall R2_1 of the storage region R2, and a copper block 24b2 is bonded to the lower surface of the inner end portion 24b1 via a bonding material or by laser welding. The lower surface of the copper block 24b2 is bonded to the bonding region 11d1 of the wiring plate 11b1. With this configuration, the wiring plate 11b1 and the output terminal 24 are electrically connected to each other.

The front surface of the wiring plate 11b2 includes a bonding region 11d2 to which a connection member for electrically connecting to a corresponding first connection terminal 22 is bonded. The inner end portion of the first connection terminal 22 is exposed to the inside from the −Y direction inner wall of the storage region R2. The inner end portion of each of the other first connection terminals 22 is exposed to the inside from the −Y direction inner wall of a corresponding one of the storage regions R1 and R3. The inner end portion has a flat plate shape, and a copper block is bonded to the lower surface of the inner end portion as the connection member. The lower surface of the copper block is bonded to the bonding region 11d2 of the wiring plate 11b2 via a bonding material. For example, an inner end portion 22b1 of the first connection terminal 22b is exposed to the inside from the inner wall R2_2 of the storage region R2, and a copper block 22b2 is bonded to the lower surface of the inner end portion 22b1 via a bonding material or by laser welding. The lower surface of the copper block 22b2 is bonded to the bonding region 11d2 of the wiring plate 11b2 via a bonding material. With this configuration, the wiring plate 11b2 and the first connection terminal 22 are electrically connected to each other.

With the above configuration, the semiconductor unit 10 constitutes an inverter circuit for one phase. The wiring plate 11b2, the semiconductor chip 13, the wiring member 14b, and the wiring plate 11b1 constitute the upper arm portion of a half-bridge circuit. The wiring plate 11b1, the semiconductor chip 12, the wiring member 14a, and the wiring plate 11b3 constitute the lower arm portion of the half-bridge circuit. The output terminal 24 connected to the wiring plate 11b1 serves as an M terminal constituting an output terminal in the half-bridge circuit. Further, the first connection terminal 22 connected to the wiring plate 11b2 serves as a P terminal constituting a positive input terminal in the half-bridge circuit, and the second connection terminal 23 connected to the wiring plate 11b3 serves as an N terminal constituting a negative output terminal in the half-bridge circuit. Switching operations of the semiconductor chips 12 and 13 are controlled in accordance with control signals, which are input to the gate electrodes (the control electrodes 12a3 and 13a3) from the control signal input terminals included in the control terminal portions 25 and 26.

The wiring member 14a integrally includes a bonding portion 14a1, a rising portion 14a2, a bridging portion 14a3, a rising portion 14a4, and a bonding portion 14a5. The lower surface of the bonding portion 14a1 is bonded to the emitter electrode 12b of the semiconductor chip 12 via a bonding material, and the lower surface of the bonding portion 14a5 is bonded to the wiring plate 11b3 via a bonding material. The wiring member 14bintegrally includes a bonding portion 14b1, a rising portion 14b2, a bridging portion 14b3, a rising portion 14b4, and a bonding portion 14b5. The lower surface of the bonding portion 14b1 is bonded to the emitter electrode 13b of the semiconductor chip 13 via a bonding material, and the lower surface of the bonding portion 14b5 is bonded to the wiring plate 11b1 via a bonding material. In the present embodiment, each of the wiring members 14a and 14b is a lead frame having an approximately flat plate shape. The wiring members 14a and 14b may be formed by bending the above-described portions.

The wiring members 14a and 14b are made of a metal containing copper and having excellent electrical conductivity. The metal may be, for example, an alloy containing aluminum in addition to copper. In order to improve corrosion resistance, the surfaces of the wiring members 14a and 14b may be plated. In this case, the plating material used is, for example, nickel, a nickel-phosphorus alloy, or a nickel-boron alloy.

For example, solder is used as the bonding material for bonding the bonding portions 14a1 and 14b1 to the semiconductor chips 12 and 13, for bonding the bonding portions 14a5 and 14b5 to the wiring plates 11b3 and 11b1, and for bonding the semiconductor chips 12 and 13 to the wiring plates 11b1 and 11b2. The solder components constituting the solder include a lead-free solder containing a predetermined alloy as a main component. The predetermined alloy contains tin. The alloy is, for example, at least one of a tin-silver alloy, a tin-silver-copper alloy, a tin-zinc-bismuth alloy, a tin-copper alloy, a tin-silver-indium-bismuth alloy, and a tin-antimony alloy. Furthermore, the solder components may include an additive. Examples of the additive include nickel, germanium, cobalt, and silicon. Therefore, examples of the solder components include tin and at least one of silver, zinc, copper, bismuth, indium, and antimony.

In addition, a sintered body may be used as the bonding material for bonding the above-described portions. When the bonding is performed by using a sintered body, the sintered material is, for example, a powder containing at least one of silver, iron, copper, aluminum, titanium, nickel, tungsten, and molybdenum.

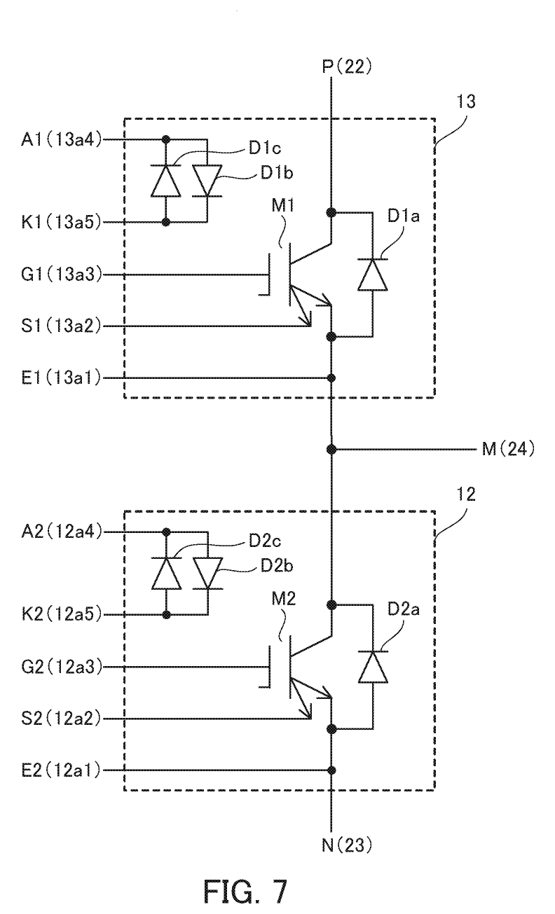

FIG. 7 is a diagram illustrating an equivalent circuit of a function of the semiconductor module according to the first embodiment. The semiconductor chip 13 includes a switching element (IGBT) M1 and a diode element (FWD) D1a constituting an RC-IGBT, and diode elements D1b and D1c for temperature sensing. The semiconductor chip 12 includes a switching element (IGBT) M2 and a diode element D2a (FWD) constituting an RC-IGBT, and diode elements D2b and D2c for temperature sensing.

The semiconductor module 2 includes an inverter circuit including the switching elements M1 and M2. The switching element M1 constitutes the upper arm portion of the half-bridge circuit, and the switching element M2 constitutes the lower arm portion of the half-bridge circuit.

The collector of the switching element M1 is connected to the P terminal constituting the positive input terminal in the half-bridge circuit. The P terminal corresponds to the first connection terminal 22. As described above, the collector electrode on the lower surface of the semiconductor chip 13 is electrically connected to the first connection terminal 22 as the P terminal via the wiring plate 11b2.

The emitter of the switching element M2 is connected to the N terminal constituting the negative input terminal in the half-bridge circuit. The N terminal corresponds to the second connection terminal 23. As described above, the emitter electrode 12b on the upper surface of the semiconductor chip 12 is electrically connected to the second connection terminal 23 as the N terminal via the wiring member 14a and the wiring plate 11b3.

The emitter of the switching element M2 is also connected to an emitter electrode E2. The emitter electrode E2 corresponds to the control electrode 12a1 of the semiconductor chip 12. The control electrode 12a1 is electrically connected to the connection terminal 25a1 via the bonding wire 15a1. The sense emitter of the switching element M2 is connected to a sense emitter electrode S2. The sense emitter electrode S2 corresponds to the control electrode 12a2 of the semiconductor chip 12. The control electrode 12a2 is electrically connected to the connection terminal 25a2 via the bonding wire 15a2.

The emitter of the switching element M1 and the collector of the switching element M2 are connected to each other, and this connection point is connected to the M terminal constituting an output terminal in the half-bridge circuit. The M terminal corresponds to the output terminal 24. As described above, the emitter electrode 13b on the upper surface of the semiconductor chip 13 is electrically connected to the collector electrode on the lower surface of the semiconductor chip 12 and the output terminal 24 via the wiring member 14b and the wiring plate 11b1.

The emitter of the switching element M1 is also connected to the emitter electrode E1. The emitter electrode E1 corresponds to the control electrode 13a1 of the semiconductor chip 13. The control electrode 13a1 is electrically connected to the connection terminal 26a1 via the bonding wire 15b1. The sense emitter of the switching element M1 is connected to a sense emitter electrode S1. The sense emitter electrode S1 corresponds to the control electrode 13a2 of the semiconductor chip 13. The control electrode 13a2 is electrically connected to the connection terminal 26a2 via the bonding wire 15b2.

The gate of the switching element M1 is connected to a gate electrode G1, which is an input electrode for a switching operation control signal. The gate electrode G1 corresponds to the control electrode 13a3 of the semiconductor chip 13. As described above, the control electrode 13a3 is electrically connected to the connection terminal 26a3 via the bonding wire 15b3, and an external connection terminal 26b at the other end of the connection terminal 26a3 forms a gate terminal corresponding to the switching element M1.

The gate of the switching element M2 is connected to a gate electrode G2, which is an input electrode for a switching operation control signal. The gate electrode G2 corresponds to the control electrode 12a3 of the semiconductor chip 12. As described above, the control electrode 12a3 is electrically connected to the connection terminal 25a3 via the bonding wire 15a3, and an external connection terminal 25b at the other end of the connection terminal 25a3 forms a gate terminal corresponding to the switching element M2.

With the above configuration, the semiconductor unit 10 including the semiconductor chips 12 and 13 constitutes an inverter circuit for one phase. In the semiconductor device 1 of the present embodiment, three semiconductor units 10a, 10b, and 10c, each of which constitutes an inverter circuit for one phase, are mounted. The inverter circuits corresponding to the semiconductor units 10a, 10b, and 10c are connected in parallel. In this case, for example, the semiconductor unit 10a generates a U-phase output voltage, the semiconductor unit 10b generates a V-phase output voltage, and the semiconductor unit 10c generates a W-phase output voltage. That is, a U-phase output voltage is output from the U-phase output terminal 24a connected to the semiconductor unit 10a, a V-phase output voltage is output from the V-phase output terminal 24b connected to the semiconductor unit 10b, and a W-phase output voltage is output from the W-phase output terminal 24c connected to the semiconductor unit 10c.

Next, a circuit configuration for temperature sensing will be described. An anode electrode A1 is connected to the anode of the diode element D1band the cathode of the diode element D1c. A cathode electrode K1 is connected to the cathode of the diode element D1band the anode of the diode element D1c. The anode electrode A1 and the cathode electrode K1 are temperature-sensing electrodes of the semiconductor chip 13. The anode electrode A1 and the cathode electrode K1 correspond to the control electrodes 13a4 and 13a5 formed on the semiconductor chip 13, respectively. The control electrodes 13a4 and 13a5 are connected to the connection terminals 26a4 and 26a5 via the bonding wires 15b4 and 15b5, respectively.

Similarly, an anode electrode A2 is connected to the anode of the diode element D2band the cathode of the diode element D2c. A cathode electrode K2 is connected to the cathode of the diode element D2b and the anode of the diode element D2c. The anode electrode A2 and the cathode electrode K2 are temperature-sensing electrodes of the semiconductor chip 12. The anode electrode A2 and the cathode electrode K2 correspond to the control electrodes 12a4 and 12a5 formed on the semiconductor chip 12, respectively. The control electrodes 12a4 and 12a5 are connected to the connection terminals 25a4 and 25a5 via the bonding wires 15a4 and 15a5, respectively.

As described above, the inside of the storage regions R1, R2, and R3 is filled with the sealing member 4. The sealing member 4 seals the semiconductor units 10, the connection terminals 25a and 26a, the bonding wires 15a and 15b, etc., in the storage regions R1, R2, and R3.

The thermosetting resin used as the sealing member 4 contracts when cured. In particular, the contraction amount during curing of epoxy resin is larger than that of silicone gel. When the sealing member 4 contracts, stress is applied to the members sealed by the sealing member 4 in the direction of the contraction. When a large stress is applied to a sealed member, this member may be damaged.

The following description assumes that the sealing member 4 in the storage regions R1, R2, and R3 contracts in the ±Y directions. Since the bonding wires 15a and 15b extend along approximately the ±Y directions, when the sealing member 4 contracts in the ±Y directions, one end or both ends of any one of the bonding wires 15a and 15b may be peeled off.

In addition, assuming that the sealing member 4 contracts in the ±Y directions, the sealing member 4 contracts toward the central portion of the storage regions R1, R2, and R3. For this reason, the contraction amount of the sealing member 4 (the movement amount of the sealing member 4 due to the contraction) is larger in the vicinity of the +Y direction inner wall and the −Y direction inner wall than in the vicinity of the center of the storage regions R1, R2, and R3, and the stress generated due to the contraction is larger. In the vicinity of the +Y direction inner wall of the storage regions R1, R2, and R3, the bonding wires 15a and 15b and the connection terminals 25a and 26a are bonded via a bonding material. As described above, in this region, a large stress is generated toward the center (that is, the −Y direction) of the storage regions R1, R2, and R3, and as a result, the bonding wires 15a and 15b and the connection terminals 25a and 26a are easily peeled off.

In the present embodiment, in order to prevent such peeling of the bonding wires 15a and 15b, the partition members 28a, 28b, and 28c (first partition members) are provided in the upper regions of the storage regions R1, R2, and R3.

The partition member 28a extends in the ±X directions in the upper region of the storage region R1, and divides the upper region (the opening) of the storage region R1 into a region R1a (a first region) and a region R1b (a second region) in plan view (see FIG. 1). The region R1a includes the bonding wires 15a and 15b (first bonding wires) and the connection terminals 25a and 26a (first connection terminals) in the storage region R1 in plan view.

Similarly, the partition member 28b extends in the ±X directions in the upper region of the storage region R2, and divides the upper region (the opening) of the storage region R2 into a region R2a (a first region) and a region R2b (a second region) in plan view (see FIG. 1). The region R2a includes the bonding wires 15a and 15b (first bonding wires) and the connection terminals 25a and 26a (first connection terminals) in the storage region R2 in plan view.

The partition member 28c extends in the ±X directions in the upper region of the storage region R3, and divides the upper region (the opening) of the storage region R3 into a region R3a (a first region) and a region R3b (a second region) in plan view (see FIG. 1). The region R3a includes the bonding wires 15a and 15b (first bonding wires) and the connection terminals 25a and 26a (first connection terminals) in the storage region R3 in plan view.

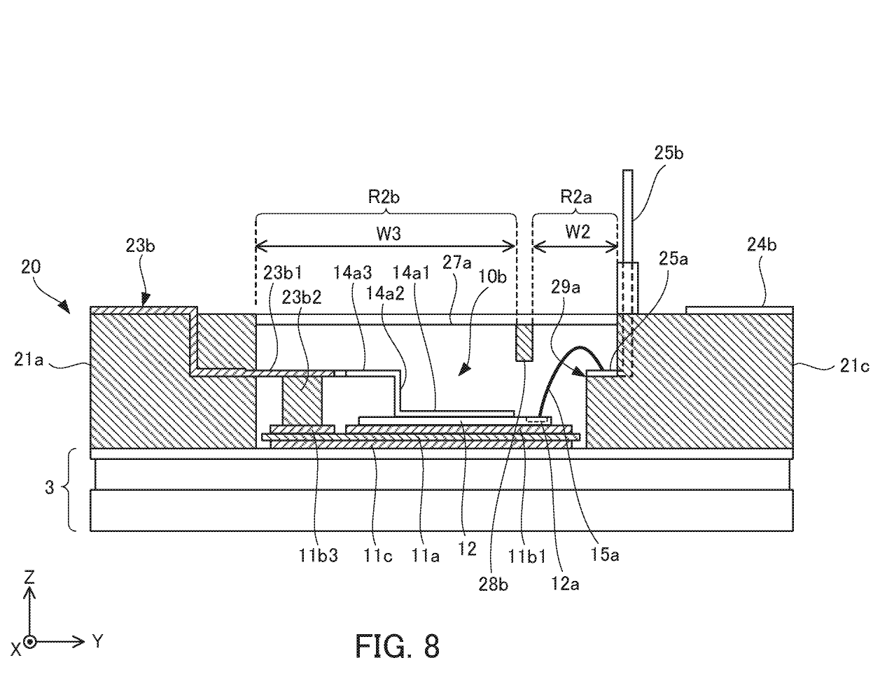

FIG. 8 is a cross-sectional view (part 2) of the semiconductor device according to the first embodiment. FIG. 8 is a cross-sectional view of the semiconductor device 1, taken along line I2-I2 in FIG. 2. In FIG. 8, the sealing member 4 is not illustrated. Among the partition members 28a, 28b, and 28c, the partition member 28b provided in the storage region R2 will be described as an example in more detail with reference to FIGS. 8 and 5.

The partition member 28b (first partition member) is provided in the upper region of the semiconductor chip 12 (a first semiconductor chip) in the storage region R2. The partition member 28b divides the storage region R2 into the region R2a (first region) including the bonding wires 15a (first bonding wires) and the connection terminals 25a (first connection terminals) and the region R2b (second region) opposite to the region R2a including the connection terminals 25a in plan view.

In the examples in FIGS. 5 and 8, the partition member 28b is formed as a beam portion bridged between the inner wall R2_3 (third inner wall, see FIG. 1) and the inner wallR2_4 (fourth inner wall, see FIG. 1) of the storage region R2. The height of the partition member 28b is equal to that of the inner walls R2_3 and R2_4 (that is, the partition walls 27a and 27b). Therefore, the sealing member 4 is injected up to the upper end of the partition walls 27a and 27b and the partition member 28b.

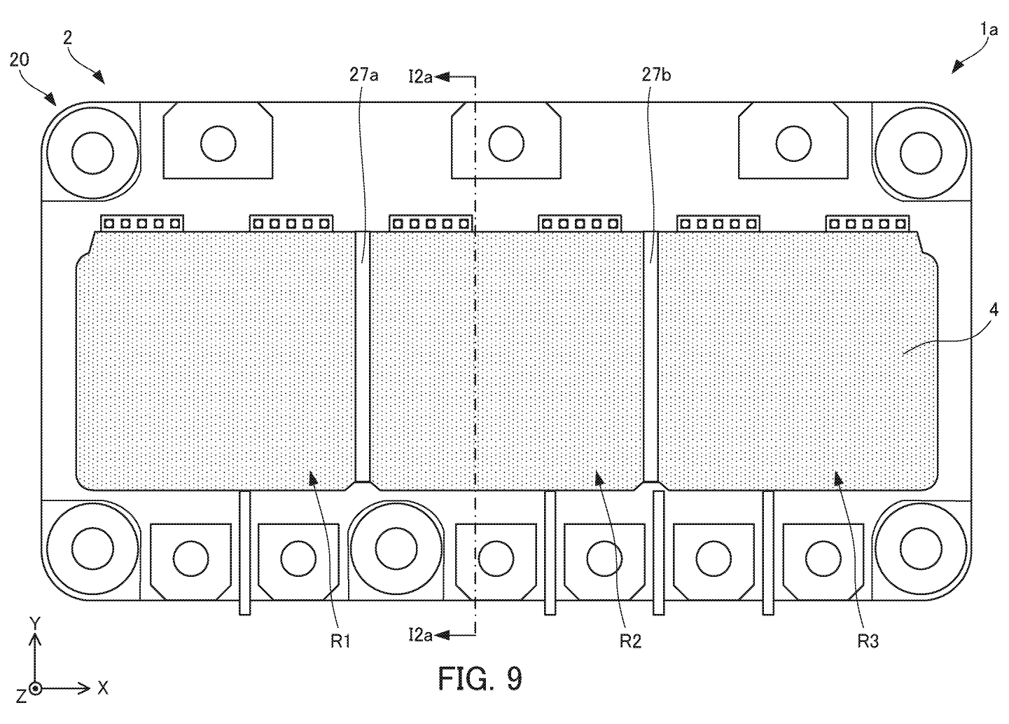

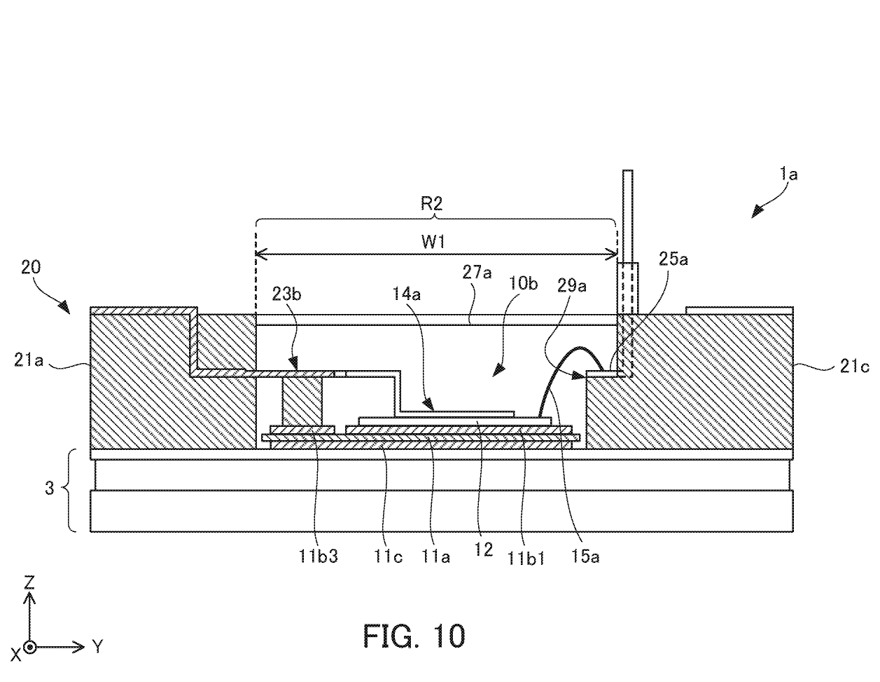

Next, a semiconductor device 1 according to a comparative example will be described with reference to FIGS. 9 and 10. The following comparative example illustrates a case where the partition members 28a, 28b, and 28c are not provided in the semiconductor device 1 according to the first embodiment.

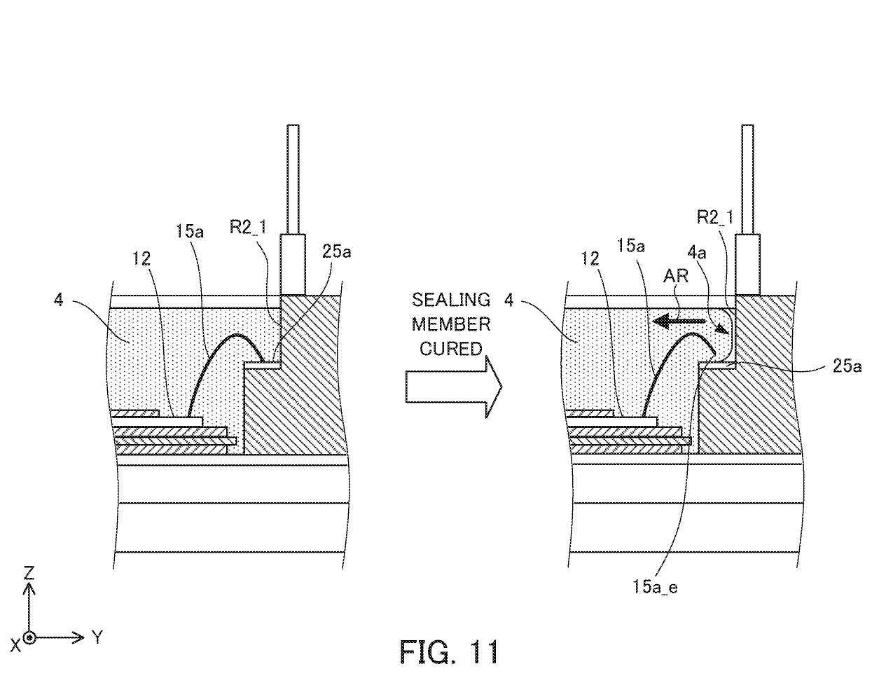

FIG. 9 is a plan view of the semiconductor device according to a comparative example. FIG. 10 is a cross-sectional view of the semiconductor device according to the comparative example. FIG. 11 is an enlarged view of a main part of the cross-sectional view illustrated in FIG. 10.

FIG. 10 is a cross-sectional view of this semiconductor device 1a (comparative example) illustrated in FIG. 9, taken along line I2a-I2a in FIG. 9. The position of line I2a-I2a with respect to the semiconductor device 1a is the same as the position of line I2-I2 with respect to the semiconductor device 1 illustrated in FIG. 2. In FIG. 10, the sealing member 4 is not illustrated. The ±Y direction width of the storage region R2 is W1. FIG. 11 is an enlarged view of a portion near the inner wall R2_1 of the storage region R2 in the cross-sectional view in FIG. 10.

In the semiconductor device 1a illustrated in FIGS. 9 and 10, the partition member 28b is not provided in the storage region R2. Therefore, in the storage region R2, the sealing member 4 contracts the ±Y directions in the entire storage region R2. The sealing member 4 contracts toward the central portion of the storage region R2 in the ±Y directions.

As illustrated in FIG. 11, in the vicinity of the +Y direction inner wall R2_1 of the storage region R2, the sealing member 4 contracts in the direction of an arrow AR (−Y direction), and stress is generated in the direction of the arrow AR. As a result, a +Y direction end portion 4a of the sealing member 4 may be peeled from the inner wall R2_1, and accordingly, a bonding end 15a_e of a bonding wire 15a may be peeled from a connection terminal 25a. In particular, when a relatively thin bonding wire 15a having a diameter of 20 μm or more and 500 μm or less is used, the bonding end 15a_e of the bonding wire 15a is easily broken from the connection terminal 25a.

On the other hand, in the semiconductor device 1 according to the first embodiment illustrated in FIGS. 5 and 8, the upper region of the storage region R2 is divided into the regions R2a and R2b by the partition member 28b. Here, the widths of the regions R2a and R2b in the ±Y directions are W2 and W3. In the upper region of the region R2a, the sealing member 4 contracts in the ±Y directions in the region having the width W2 smaller than the width W1 of the entire storage region R2. Therefore, the contraction amount of the sealing member 4 in the upper region of the region R2a is smaller than the contraction amount of the sealing member 4 in the same region in the above-described case where the partition member 28b is not provided.

Therefore, the ±Y direction stress generated by the contraction of the sealing member 4 in the vicinity of a bonding wire 15a, particularly, in the vicinity of the connection portion between a bonding wire 15a and a connection terminal 25a, is smaller in the case where the partition member 28b is provided. As a result, the possibility of peeling of the bonding wire 15a from the connection terminal 25a is reduced.

In order to reduce the possibility of peeling of the bonding wire 15a from the connection terminal 25a, it is desirable that the partition member 28b extend to a position as low as possible in the downward direction (−Z direction). On the other hand, from the viewpoint of ease of the operation of bonding the bonding wire 15a to a control electrode 12a of the semiconductor chip 12, it is desirable that the lower end of the partition member 28b and the pair of the bonding wire 15a and the control electrode 12a are spaced apart from each other to such an extent that the bonding operation is not hindered.

It is desirable that the lower end of the partition member 28b extend to the height of the upper surface of the step 29a. When the lower end of the partition member 28b does not reach the height of the upper surface of the step 29a, the sealing member 4 in the vicinity of the bonding portion between the bonding wire 15a and the connection terminal 25a is not partitioned by the partition member 28b. Since the lower end of the partition member 28b is located at the height of the upper surface of the step 29a, the sealing member 4 in the vicinity of the bonding portion between the bonding wire 15a and the connection terminal 25a is partitioned by the partition member 28b. Therefore, it is possible to reduce the impact of the stress due to the sealing member 4 in the vicinity of the bonding portion. For example, by setting the ±Y direction position of the partition member 28b in the −Y direction from the control electrode 12a, it is possible to extend the lower end of the partition member 28b to the height of the step 29a while securing the workability for bonding the bonding wire 15a and the control electrode 12a.

In plan view, the region R2b includes the wiring member (lead frame) 14a (first wiring member) bonded to the emitter electrode 12b (first main electrode) of the semiconductor chip 12 (first semiconductor chip) and the wiring plate 11b3 (second wiring pattern). The ±Y direction width W3 of the region R2b is larger than the ±Y direction width W2 of the region R2a. Therefore, the ±Y direction contraction amount of the sealing member 4 in the upper region of the region R2a is larger than the contraction amount in the upper region of the region R1a. However, the bonding strength between the wiring member 14a and the pair of the emitter electrode 12b and the wiring plate 11b3 is much larger than the bonding strength between the bonding wire 15a and the connection terminal 25a. Therefore, the wiring member 14a is less likely to be peeled from the emitter electrode 12b and the wiring plate 11b3 by the ±Y direction contraction of the sealing member 4 in the region R2b.

In plan view, the region R2a includes the plurality of connection terminals 25a (connection terminals 25a1, 25a2, 25a3, 25a4, and 25a5) and the plurality of bonding wires 15a (bonding wires 15a1, 15a2, 15a3, 15a4, and 15a5). Further, in plan view, the region R2a includes the plurality of connection terminals 26a (connection terminals 26a1, 26a2, 26a3, 26a4, and 26a5) and the plurality of bonding wires 15b (bonding wires 15b1, 15b2, 15b3, 15b4, and 15b5). The region R2a may include the plurality of control electrodes 12a (control electrodes 12a1, 12a2, 12a3, 12a4, and 12a5) of the semiconductor chip 12 and the plurality of control electrodes 13a (control electrodes 13a1, 13a2, 13a3, 13a4, and 13a5) of the semiconductor chip 13.

On the other hand, in plan view, the region R2b does not include any of the connection terminals 25a and 26a and the bonding wires 15a and 15b, and does not include any of the control electrodes 12a and 13a. As described above, in plan view, the connection terminals 25a and 26a and the bonding wires 15a and 15b are not provided in the region R2b, but they are gathered in the region R2a. In this way, it is possible to effectively prevent the bonding wires 15a and 15b from being peeled from the connection terminals 25a and 26a due to contraction of the sealing member 4. In addition, in plan view, the control electrodes 12a and 13a and the bonding wires 15a and 15b are not provided in the region R2b, but they are gathered in the region R2a. In this way, it is possible to effectively prevent the bonding wires 15a and 15b from being peeled from the control electrodes 12a and 13a due to contraction of the sealing member 4.

In plan view, the wiring members 14a and 14b, which are solid plate-shaped metal materials, are disposed in the region R2b, and the lower surfaces of the bonding portions 14a5 and 14b5 of the wiring members 14a and 14b are bonded to the upper surfaces of the wiring plates 11b3 and 11b1. In plan view, the copper blocks 22b2, 23b2, and 24b2 connected to the inner end portion 22b1 of the first connection terminal 22, the inner end portion 23b1 of the second connection terminal 23, and the inner end portion 24b1 of the output terminal 24, respectively, are disposed in the region R2b. The lower surfaces of the copper blocks 22b2, 23b2, 24b2 are bonded to the upper surfaces of the wiring plates 11b2, 11b3, 11b1. Since each bonding is performed between surfaces, the bonding area is larger than that of the bonding wires 15a and 15b. Therefore, the bonding force is strong, and peeling is not easy. Therefore, peeling due to contraction of the sealing member 4 is less likely to occur in these bonding portions, and there will be no particular problem even if these bonding portions are disposed in the region R2b, which is a wider region than the region R2a.

Since W2 is less than W3 as described above, the area of the region R2a is smaller than that of the region R2b in plan view. Thus, the contraction amount of the sealing member 4 in the region R2a including the bonding wires 15a is smaller than the contraction amount of the sealing member 4 in the region R2b including the wiring member (lead frame) 14a. Therefore, the possibility of peeling of the bonding wires 15a from the connection terminals 25a is reduced.

In the examples in FIGS. 5 and 8, the partition member 28b extends in the ±X directions in the upper region of the storage region R2. That is, the partition member 28b is disposed to face the inner wall R2_1 (first inner wall, see FIG. 1) of the storage region R2. Thus, the bonding wires 15a and the connection terminals 25a are included in the region R2a in plan view, and the possibility of peeling of the bonding wires 15a from the connection terminals 25a is reduced.

In the examples in FIGS. 5 and 8, the partition member 28b is disposed between the control electrodes 12a (first control electrode) and the wiring member 14a (first wiring member) in plan view. As a result, in a state where the bonding wires 15a and the connection terminals 25a are included in the region R2a in plan view, the workability for bonding the bonding wires 15a and the control electrodes 12a is ensured. In addition, by reducing the ±Y direction width W2 of the region R2a, it is possible to enhance the effect of preventing peeling of the bonding wires 15a from the connection terminals 25a.

In the examples in FIGS. 5 and 8, the lower end of the partition member 28b has the same height. However, a part of the partition member 28b may have a lower height. For example, when viewed in the +Y direction as illustrated in FIG. 5, the height of the partition member 28b may be reduced within a range in which the partition member 28b does not interfere with the bonding wires 15a and 15b or the inner end portion 24b1 of the output terminal 24. As a specific example, the lower end of the partition member 28b may extend to the vicinity of the wiring plates 11b1 and 11b2 or to a position in contact with the wiring plate 11b1 or 11b2 in a range from a position away from a bonding wire 15a by a certain distance in the −X direction to the partition wall 27a and in a range from a position away from a bonding wire 15b by a certain distance in the +X direction to the partition wall 27b.

Next, a modification in which a part of the semiconductor device 1 according to the first embodiment is modified will be described.

### Second Embodiment

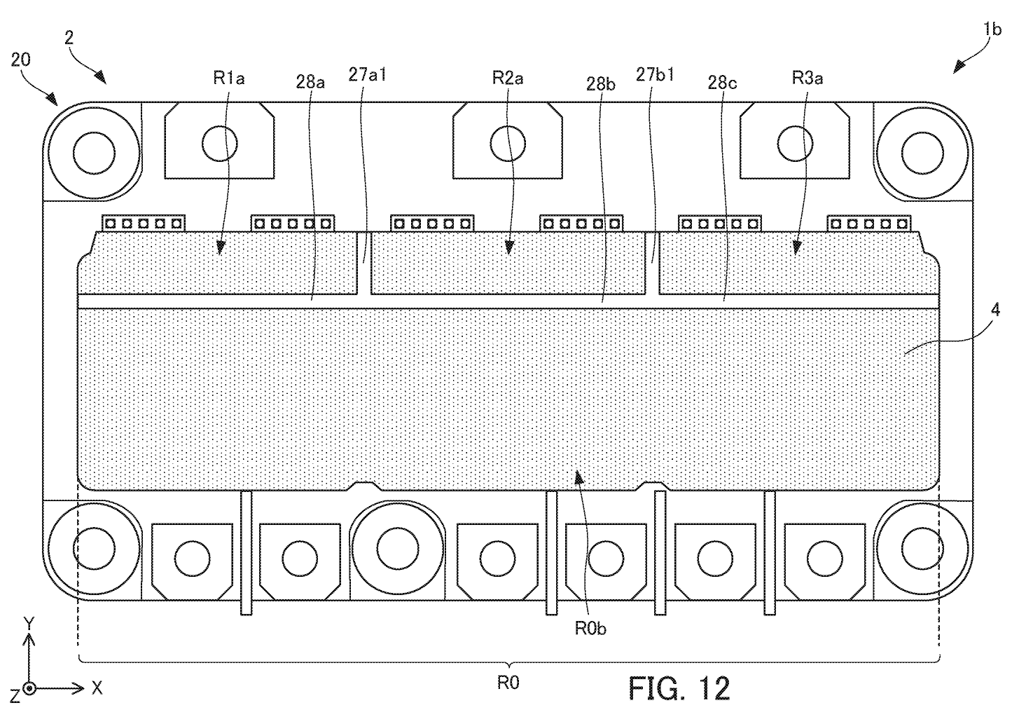

FIG. 12 is a plan view of a semiconductor device according to a second embodiment.

In this semiconductor device 1b according to the second embodiment, a region obtained by combining the storage regions R1, R2, and R3 in the first embodiment will be referred to as an entire region R0. In the semiconductor device 1b, a member of the partition wall 27a, the member being located between the region R1b and the region R2b, and a member of the partition wall 27b, the member being located between the region R2b and the region R3b, in the first embodiment are removed. Thus, a region R0b in which the regions R1b, R2b, and R3b are integrated is formed.

On the other hand, a member of the partition wall 27a, the member being located between the region R1a and the region R2a, and a member of the partition wall 27b, the member being located between the region R2a and a region R3a, are left as partition walls 27a1 and 27b1 (third partition members). A partition member 28a extending in the ±X directions is provided between the −X side inner wall of the entire region R0 and the partition wall 27a1. A partition member 28b extending in the ±X directions is provided between the partition wall 27a1 and the partition wall 27b1. A partition member 28c extending in the ±X directions is provided between the partition wall 27b1 and the +X direction inner wall of the entire region R0.

Thus, the same regions R1a, R2a, and R3a as those in the first embodiment are formed. Since the ±Y direction widths of the regions R1a, R2a, and R3a are smaller than the ±Y direction width of the entire region R0, it is possible to reduce the possibility that the bonding wires 15a are peeled from the connection terminals 25a included in the regions R1a, R2a, and R3a in plan view due to the contraction of a sealing member 4.

On the other hand, the region R0b does not include the bonding wires but includes wiring members (lead frames) having a higher bonding strength with electrodes than the bonding wires. In the region R0b, the wiring members are less likely to peeled due to the contraction of the sealing member 4.

In the second embodiment, connection terminals 25a and 26a (first and second connection terminals) are sequentially provided along the +X direction (first direction) along an inner wall R2_1 (first inner wall). In the individual semiconductor unit 10, a semiconductor chip 13 (second semiconductor chip) is disposed on the +X direction side of a semiconductor chip 12 (first semiconductor chip), and a wiring member 14b (second wiring member) is connected to an emitter electrode 13b (second main electrode) on the upper surface of the semiconductor chip 13. Control electrodes 13a (second control electrodes) are formed on the upper surface of the semiconductor chip 13 in the direction of the inner wall R2_1 side from the wiring member 14b via the wiring member 14b and bonding wires 15b (second bonding wires). A plurality of semiconductor units 10 (semiconductor units 10a, 10b, and 10c) including the semiconductor chips 12 and 13 as described above are arranged parallel with the inner wall R2_1. The partition walls 27a1 and 27b1 (second partition members) are provided to divide the region on the +Y direction side of the partition members 28a, 28b, and 28c in the storage region including the semiconductor units 10a, 10b, and 10c into the regions R1a, R2a, and R3a including the semiconductor units 10a, 10b, and 10c, respectively, in plan view.

### Third Embodiment

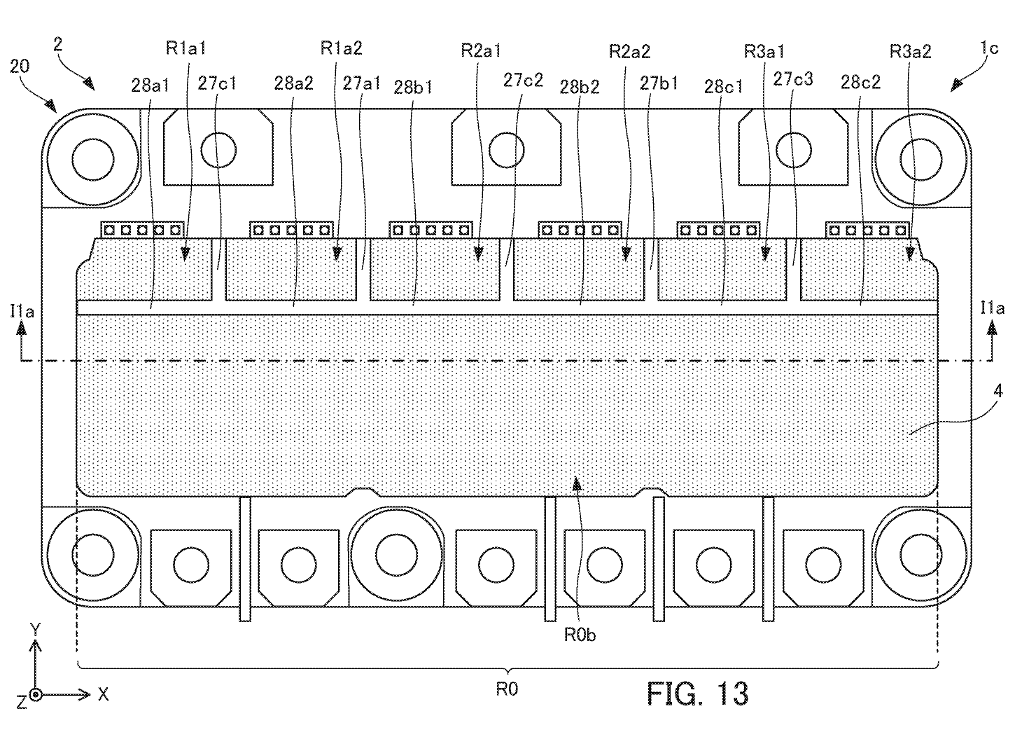

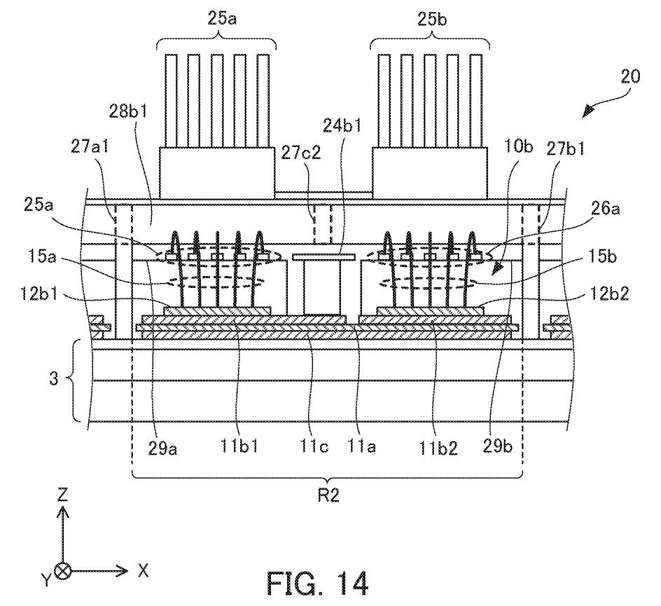

FIG. 13 is a plan view of a semiconductor device according to a third embodiment. FIG. 14 is a cross-sectional view of the semiconductor device according to the third embodiment. FIG. 14 is an enlarged cross-sectional view of this semiconductor device 1c according to the third embodiment taken along line I1a-I1a in FIG. 13, illustrating the vicinity of the semiconductor unit 10b. The position of line I1a-I1a with respect to the semiconductor device 1c is the same as the position of line I1-I1 with respect to the semiconductor device 1 illustrated in FIG. 2.

In the semiconductor device 1c, the upper region of the region R1a illustrated in FIG. 12 is divided in the ±X directions by a partition member 27c1, to form regions R1a1 and R1a2. In plan view, the region R1a1 includes bonding wires 15a and connection terminals 25a, and the region R1a2 includes bonding wires 15b and connection terminals 26a.

The upper region of the region R2a illustrated in FIG. 12 is divided in the ±X directions by a partition member 27c2, to form regions R2a1 and R2a2. In plan view, the region R2a1 includes bonding wires 15a and connection terminals 25a, and the region R2a2 includes bonding wires 15b and connection terminals 26a.

Further, the upper region of the region R3a illustrated in FIG. 12 is divided in the ±X directions by a partition member 27c3, to form regions R3a1 and R3a2. In plan view, the region R3a1 includes bonding wires 15a and connection terminals 25a, and the region R3a2 includes bonding wires 15b and connection terminals 26a.

The height of the lower end of the partition member 27c1 is the same as that of the lower end of the partition member 28a (28a1, 28a2). The height of the lower end of the partition member 27c2 is the same as that of the lower end of the partition member 28b (28b1, 28b2). The height of the lower end of the partition member 27c3 is the same as that of the lower end of the partition member 28c (28c1, 28c2). For example, as illustrated in FIG. 14, an inner end portion 24b1 of a V-phase output terminal 24b is disposed below (−Z side) the partition member 27c2. The height of the lower end of the partition member 27c2 is set so as not to contact the upper surface of the inner end portion 24b1.

In the semiconductor device 1c according to the third embodiment, the regions R1a1, R1a2, R2a1, R2a2, R3a1, and R3a2 having the ±X direction width less than that of the regions R1a, R2a, and R3a in FIG. 2 are formed. In these regions R1a1, R1a2, R2a1, R2a2, R3a1, and R3a2, the contraction amount in the ±X directions when the sealing member 4 is cured is also reduced. Therefore, it is possible to reduce the possibility that the bonding wires 15a are peeled from the connection terminals 25a in the regions R1a1, R2a1, and R3a1. In addition, it is possible to reduce the possibility that the bonding wires 15b are peeled from the connection terminals 26a in the regions R1a2, R2a2, and R3a2.

In the third embodiment, the connection terminals 25a and 26a (first and second connection terminals) are sequentially provided in the +X direction (first direction) along the inner wall R2_1 (first inner wall). In the individual semiconductor unit 10, a semiconductor chip 13 (second semiconductor chip) is disposed on the +X direction side of a semiconductor chip 12 (first semiconductor chip), and a wiring member 14b (second wiring member) is connected to an emitter electrode 13b (second main electrode) on the upper surface of the semiconductor chip 13. Control electrodes 13a (second control electrodes) are formed on the upper surface of the semiconductor chip 13 in the direction of the inner wall R2_1 side from the wiring member 14b via the wiring member 14b and bonding wires 15b (second bonding wires). The partition members 27c1, 27c2, and 27c3 (third partition members) are provided to divide the regions R1a, R2a, and R3a (first regions) on the +Y direction side of the partition members 28a, 28b, and 28c in the storage regions R1, R2, and R3 including the semiconductor chips 12 and 13 into the regions R1a1, R2a1, and R3a1 (third regions) including the bonding wires 15a (first bonding wires) and the connection terminals 25a (first connection terminals) and the regions R1a2, R2a2, and R3a2 (fourth regions) including the bonding wires 15b (second bonding wires) and the connection terminals 26a (first connection terminals) in plan view.

According to the disclosed techniques, it is possible to reduce the occurrence of peeling of bonding wires due to contraction when a sealing member is cured.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a heat dissipation base having an upper surface;
a semiconductor unit disposed on the upper surface of the heat dissipation base, the semiconductor unit including a first semiconductor chip that has a first control electrode on an upper surface of the first semiconductor chip;
an outer peripheral wall having a lower end thereof in contact with the upper surface of the heat dissipation base, the outer peripheral wall surrounding the semiconductor unit to define a storage region with the upper surface of the heat dissipation base, the semiconductor unit being in the storage region;
a first connection terminal provided apart from the semiconductor unit in the storage region;
a first bonding wire electrically connecting the first connection terminal and the first control electrode of the first semiconductor chip;
a sealing member sealing the storage area; and
a first partition member provided above the first semiconductor chip in the storage region, to thereby divide the storage region into a first region and a second region, the first connection terminal and the first bonding wire being in the first region, and the first connection terminal being in the second region, in a plan view of the semiconductor device.

2. The semiconductor device according to claim 1,
wherein the outer peripheral wall includes a first inner wall,
wherein the first connection terminal is provided on the first inner wall, and
wherein the first partition member is disposed to face the first inner wall.

3. The semiconductor device according to claim 2,
wherein the first semiconductor chip further includes a first main electrode provided on the upper surface of the first semiconductor chip, the first main electrode being farther from the first inner wall than the first control electrode,
wherein the semiconductor unit further includes a first wiring member bonded to the first main electrode via a bonding material, and
wherein the first partition member is disposed between the first control electrode and the first wiring member in the plan view.

4. The semiconductor device according to claim 3,
wherein the semiconductor unit further includes:
an insulating substrate disposed on the upper surface of the heat dissipation base,
a first wiring pattern formed on an upper surface of the insulating substrate, and
a second wiring pattern formed on the upper surface of the insulating substrate, and being farther from the first inner wall than the first wiring pattern,
wherein the first semiconductor chip is disposed on an upper surface of the first wiring pattern, and
wherein the first wiring member electrically connects the first main electrode of the first semiconductor chip and an upper surface of the second wiring pattern.

5. The semiconductor device according to claim 3,
wherein the semiconductor unit is provided in plurality and arranged in the storage area in a first direction which is along the first inner wall in the plan view,
wherein the first connection terminal is provided in plurality,
wherein the first inner wall further includes a plurality of second connection terminals paired respectively with the plurality of first connection terminals, to thereby form a plurality of pairs of the first and second connection terminals, the plurality of second connection terminals being arranged in the first direction with respect to the plurality of first connection terminals,
wherein each of the plurality of semiconductor units further includes
a second semiconductor chip disposed in the first direction with respect to the first semiconductor chip in said each semiconductor unit,
a second wiring member electrically connected to a second main electrode on an upper surface of the second semiconductor chip via another bonding material, and
a second control electrode formed on the upper surface of the second semiconductor chip, the second control electrode being located closer to the first inner wall than the second wiring member, and being electrically connected to the second connection terminal via a second bonding wire,
wherein the plurality of pairs of the first and second connection terminals are provided for the plurality of semiconductor units, respectively, each pair being electrically connected to the first control electrode and the second control electrode included in the corresponding semiconductor unit via the first bonding wire and the second bonding wire, respectively, and
wherein the semiconductor device further includes a second partition member partitioning the first region into a plurality of sub-regions, which respectively have the plurality of semiconductor units therein, in the plan view.

6. The semiconductor device according to claim 3,
wherein the first inner wall includes a second connection terminal arranged in a first direction, which is along the first inner wall in the plan view, with respect to the first connection terminal,
wherein the semiconductor unit includes
a second semiconductor chip disposed in the first direction with respect to the first semiconductor chip,
a second wiring member electrically connected to a second main electrode on an upper surface of the second semiconductor chip via another bonding material, and
a second control electrode formed on the upper surface of the second semiconductor chip, the second control electrode being located closer to the first inner wall than the second wiring member, and being electrically connected to the second connection terminal via a second bonding wire, and
wherein the semiconductor device further includes a third partition member dividing the first region into a third region and a fourth region, the first connection terminal and the first bonding wire being in the third region, and the second connection terminal and the second bonding wire being in the fourth region, in the plan view.

7. The semiconductor device according to claim 6, wherein the third partition member is bridged between the first partition member and the first inner wall.

8. The semiconductor device according to claim 3, wherein the first wiring member is a plate-shaped metal material.

9. The semiconductor device according to claim 2,
wherein the outer peripheral wall further includes:
a second inner wall facing the first inner wall, each of the first inner wall and the second inner wall having two ends,
a third inner wall connecting one end of the first inner wall and one end of the second inner wall, and
a fourth inner wall connecting the other end of the first inner wall and the other end of the second inner wall, and
wherein the first partition member is bridged between the third inner wall and the fourth inner wall.

10. The semiconductor device according to claim 2,
wherein the first inner wall has an inwardly protruding step formed thereon, and
wherein the first connection terminal is provided on the inwardly protruding step.

11. The semiconductor device according to claim 1, wherein an area of the first region is smaller than an area of the second region in the plan view.

12. The semiconductor device according to claim 1, wherein the second region does not have any bonding wire therein in the plan view.

13. The semiconductor device according to claim 12,
wherein the outer peripheral wall includes a first inner wall,
wherein the first connection terminal is provided in plurality and arranged in a first direction, which is along the first inner wall, on the first inner wall of the outer peripheral wall in the plan view,
wherein the first control electrode is provided in plurality and arranged in the first direction on the upper surface of the first semiconductor chip in the plan view, the plurality of first control electrodes corresponding one-to-one to the plurality of first connection terminals,
wherein the semiconductor device includes the first bonding wire in plurality, each of the plurality of first bonding wires electrically connecting a corresponding one of the plurality of first connection terminals to a corresponding one of the plurality of first control electrodes, the corresponding first control electrode corresponding to the corresponding first connection terminal,
wherein the first partition member is disposed to face the first inner wall, and
wherein the plurality of first connection terminals and the plurality of bonding wires are in the first region in the plan view.
